(19) United States
(12) Patent Application Publication
(10) Pub. No.: US 2026/0259504 A1
(43) Pub. Date: Sep. 3, 2026

(54) OPTICAL ELEMENT AND EUV LITHOGRAPHY SYSTEM

(71) Applicant: Carl Zeiss SMT GmbH, Oberkochen (DE)

(72) Inventor: Peter HUBER, Heidenheim (DE)

(21) Appl. No.: 19/653,191

(22) Filed: Apr. 21, 2026

Related U.S. Application Data
(63) Continuation of application No. PCT/EP2024/077431, filed on Sep. 30, 2024.

(30) Foreign Application Priority Data
Oct. 24, 2023 (DE) 10 2023 210 486.5

(51) Int. Cl. G03F 7/00; G02B 5/08

(52) U.S. Cl. CPC G03F 7/70233; G02B 5/0816; G02B 5/0891; G03F 7/702

(57) ABSTRACT

An optical element (25) for reflecting EUV radiation (16), includes a substrate (26), a reflective coating (27) for reflecting the EUV radiation, and an etchable material (29), which is covered by the reflective coating and is removed on contact with an etching medium (31). In a first aspect, the reflective coating is under a mechanical prestress in order to cause the reflective coating to curve toward the substrate when the etchable material is removed by the etching medium if the reflective coating is damaged. In a second aspect, the etchable material is doped with a dopant (36) that is not removed on contact with the etching medium, and that preferably accumulates at an etching front (37) of the etchable material when the etchable material is removed by the etching medium if the reflective coating is damaged.

### CROSS-REFERENCE TO RELATED APPLICATION

This is a Continuation of International Application PCT/EP2024/077431, which has an international filing date of September 30, 2024, and the disclosure of which is incorporated in its entirety into the present Continuation by reference. This Continuation also claims foreign priority under 35 U.S.C. §119(a)-(d) to and also incorporates by reference, in its entirety, German Patent Application DE 10 2023 210 486.5 filed October 24, 2023.

### FIELD

The invention relates to an optical element for reflecting EUV radiation, comprising: a substrate, a reflective coating for reflecting the EUV radiation, and an etchable material, which is covered by the reflective coating and is removed on contact with an etching gas or is removable on contact with an etching gas. The invention also relates to an EUV lithography system comprising at least one such optical element.

### BACKGROUND

For the purposes of this application, an EUV lithography system is understood as meaning an optical system or an optical arrangement for EUV lithography, i.e. an optical system that can be used in the field of EUV lithography. Apart from an EUV lithography apparatus used for producing semiconductor components, the optical system can be for example an inspection system for the inspection of a photomask (hereinafter also referred to as a reticle) used in an EUV lithography apparatus, for the inspection of a semiconductor substrate to be structured (hereinafter also referred to as a wafer), or a metrology system used for measuring an EUV lithography apparatus or parts thereof, for example for measuring a projection system.

EUV (“Extreme UltraViolet”) radiation is understood to mean radiation in a wavelength range between about 5 nm and about 30 nm, for example at 13.5 nm. Since EUV radiation is greatly absorbed by most known materials, the EUV radiation is typically guided through the EUV lithography system with reflective optical elements.

Optical elements for reflecting EUV radiation, which are also referred to as EUV mirrors below, are exposed to harsh conditions during operation in an EUV lithography system, in particular in an EUV lithography apparatus. For example, EUV radiation having a high radiant power impinges on the reflective coating. Residual gases in a vacuum environment in which the EUV mirrors are generally operated (e.g. oxygen, nitrogen, hydrogen, water, and further residual gases routinely found in ultra-high vacuum) can be converted into reactive species such as ions or radicals, for example into a hydrogen-containing plasma, by the action of the EUV radiation.

Below the reflective coating there may be an etchable material that is etched away or removed on contact with an etching medium, for example in the form of an etching gas, e.g. in the form of hydrogen radicals. In principle, this is unproblematic if the reflective coating covers the etchable material without gaps. However, if the reflective coating is damaged and has local damaged sites, e.g. in the form of holes, the etching medium can penetrate through to the etchable material located under the reflective coating and remove this material. This results in the reflective coating being underetched at the location of the respective damaged site and in the surroundings of the damaged site during operation of the optical element. The underetching can produce very large defective regions on the optical surface of the reflective optical element. The same is true if the surface of the reflective coating is cleaned by a plasma or is wet-chemically cleaned, e.g. with an etching cleaning medium such as an acid. In this case too, the etching cleaning medium may possibly penetrate through holes or other damage in the reflective coating to areas underneath and partially etch away the etchable material.

DE102019212736A1 describes an optical element for reflecting EUV radiation, comprising a coating that reflects EUV radiation and to which a capping layer is applied. Arranged between the reflective coating and the capping layer is an intermediate layer, which comprises at least one reactive material that, together with an activating gas penetrating through a gap in the capping layer, forms at least one reaction product that seals the gap.

DE102015225510A1 describes a mirror element comprising a substrate and a layer stack comprising at least one reflection layer system. A curvature of the mirror element is generated based on a desired target curvature for a predefined operating temperature by a non-vanishing bending force exerted by the layer stack. The generated curvature varies by no more than 10% over a temperature interval of at least 10 K.

DE102018204364A1 describes an optical arrangement for EUV lithography, comprising at least one component having a main body with at least one surface region that is exposed to activated hydrogen during operation of the optical arrangement. The main body contains at least one material that forms at least one volatile hydride on contact of the surface region with the activated hydrogen. At the surface region, noble metal ions are implanted into the main body. Noble metals, in particular in the form of noble metal ions, generally have a strong catalytic effect for the recombination of activated hydrogen to form molecular hydrogen and are intended to prevent the formation of the volatile hydride.

DE102020213639A1 describes a reflective optical element for reflecting EUV radiation, comprising a substrate and a reflective coating applied to the substrate. The reflective coating, a structured layer, which is formed between the substrate and the reflective coating, and/or the substrate is/are doped with at least one noble metal.

### SUMMARY

One object of the invention is to provide an optical element and an EUV lithography system in which material removal of the etchable material is spatially limited in the event of damage to the reflective coating.

According to a first aspect, this object is addressed by an optical element of the type set forth hereinabove, in which the reflective coating is under a mechanical prestress causing the reflective coating to curve toward the substrate when the etchable material is removed by the etching medium in the event of damage to the reflective coating.

In this aspect, it is proposed to place the reflective coating under a mechanical prestress in order to generate a bending force or a bending moment. The bending force is so small that it has only a slight effect on the substrate or on the surface thereof and only negligibly curves the substrate, if at all. However, the bending force is sufficient to curve the reflective coating toward the substrate when the etchable material located under the reflective coating is removed. The prestress of the reflective coating generates, optionally in combination with a further layer arranged between the reflective coating and the substrate (see below), a force or a bending moment toward the substrate.

As described further above, the etchable material is removed when the reflective coating has a damaged site, for example in the form of a hole or the like, wherein in this case the etchable material is removed not only directly below the damaged site but also in surroundings of the damaged site, i.e. the reflective coating is underetched in the surroundings of the damaged site. In this case, on account of the bending force, the underetched part of the reflective coating curves toward the substrate, more specifically toward a cavity formed by the etching of the material and thus prevents the etching medium (e.g. in the form of a plasma) passing through the damaged site from accessing an etching front on the removed material. If the etching medium, e.g. in the form of one or more etching gases such as a hydrogen plasma, no longer reaches the etching front, the lateral extent of the removed region is limited. The etchable material may in particular be a material that forms volatile hydrides with hydrogen.

In one development of this embodiment, the reflective coating is under compressive stress at least in a coating portion facing away from the substrate. The coating portion facing away from the substrate typically extends from a surface of the reflective coating facing away from the substrate into the reflective coating over a predefined thickness or depth. The coating portion facing away from the substrate may have one or more layers under compressive stress. The compressive stress of the coating portion facing away from the substrate may be combined with a tensile stress (see below) in order to curve the reflective coating toward the substrate in the manner of a bimetallic strip when the underlying etchable material is removed. By contrast with a bimetallic strip, the bending force is not produced by differential thermal expansion, but instead the bending force or the bending moment typically results from the compressive stress in combination with a tensile stress or from differential compressive stress of two or more layers, wherein the layer(s) arranged further away from the substrate have a greater compressive stress than the layer(s) arranged closer to the substrate.

In one development of this embodiment, the reflective coating is under tensile stress at least in a coating portion facing toward the substrate. The coating portion facing toward the substrate typically extends from a surface facing toward the substrate into the reflective coating over a predetermined thickness. In the coating portion facing toward the substrate, the reflective coating may have one or more layers under tensile stress. In this embodiment, the coating may consist of the coating portion that faces away from the substrate and is under compressive stress and the coating portion that faces toward the substrate and is under tensile stress. In this case, the reflective coating bends toward the substrate on account of the mechanical prestress or the bending force when the underlying etchable material is removed. In principle, it is also possible for a further coating portion, which is not under tensile stress or compressive stress, to be located between the coating portion under compressive stress and the coating portion under tensile stress.

As described further above, at least in the coating portion facing toward the substrate, the reflective coating may alternatively be under a compressive stress that is smaller than the compressive stress in the coating portion facing away from the substrate. In this case too, the prestress of the reflective coating may cause the reflective coating to curve toward the substrate when the etchable material is removed.

Whether a compressive or tensile stress occurs in the first and/or in the second coating portion and the magnitude of the compressive or tensile stress can be influenced by the respective production method or coating method during the application of the respective layer(s) and by the layer material used. In principle, there are materials that tend to form tensile stresses and materials that tend to form compressive stresses, wherein the formation of a tensile or compressive stress can be influenced by the production method.

The production methods for the reflective coating are typically coating methods in the form of physical vapor deposition (PVD) methods such as e.g. thermal evaporation or e-beam/electron-beam evaporation, ion beam & magnetron sputtering or pulsed laser deposition, or coating methods based on chemical vapor deposition (CVD). Other coating methods, e.g. atomic layer deposition (ALD), are also possible.

The one or more materials of the coating portion facing away from the substrate may for example be applied using a method that typically produces a compressive stress. For example, the coating portion facing away from the substrate may be applied by sputtering, since this coating method typically produces a compressive stress. The coating portion facing toward the substrate may for example be produced through electron beam evaporation, which generally produces a tensile stress rather than a compressive stress.

In an alternative development, the entire reflective coating is under compressive stress and at least one layer under tensile stress is arranged between the reflective coating and the etchable material. Even if the reflective coating is under tensile stress in a coating portion facing toward the substrate, at least one layer under tensile stress may be arranged between the reflective coating and the etchable material.

As described further above, there are in principle materials that tend to form tensile stresses and materials that tend to form compressive stresses. The materials used for the layers of the reflective coating have an optical function and therefore cannot be selected arbitrarily. This does not apply to the material of the layer under tensile stress, since this layer generally does not perform an optical function. The material of the layer under tensile stress may be, for example, Mo, MoSi, Mo/Si multilayer, MgF2, Ni, Cr or Cr alloys. The layer under tensile stress ideally directly adjoins the reflective coating under compressive stress in order to produce the greatest possible bending force, but this is not absolutely necessary.

As an alternative to the layer under tensile stress, at least one layer under compressive stress may be arranged between the reflective coating and the etchable material, wherein the compressive stress of this layer is lower than the compressive stress of the reflective coating. In this case too, a bending moment and thus a curvature of the reflective coating toward the substrate may be produced. However, the smaller the difference between the two compressive stresses is, the smaller the bending moment and thus the curvature of the reflective coating will be. It is therefore generally more advantageous to use a layer under tensile stress than a layer under compressive stress.

According to a second aspect, an optical element of the type set forth above is provided, in which the etchable material is doped with a dopant that is not removed or not removable on contact with the etching medium. The dopant preferably accumulates at an etching front of the etchable material when the etchable material is removed by the etching medium in the event of damage to the reflective coating. Since the etching medium is generally atomic hydrogen or a hydrogen plasma, suitable dopants are in principle any materials that do not form volatile hydrides. Preferably, the materials used as dopants are those that interfere as little as possible with the further process steps (cleaning, polishing, measuring, structuring, plasma treatment, coating, etc.) and that are also stable with respect to EUV radiation and thermal loading over their lifetime. The inventors have found that, when the etchable material is being removed, the dopant typically accumulates at the etching front and forms an e.g. mesh-like structure there, thus resulting in the formation of a passivation layer on the incipiently etched material after a short time. This passivation layer prevents further removal of material, i.e. the removal of material through etching comes to a standstill.

In one development of this embodiment, the dopant is selected from the group comprising: metals, oxides, preferably SiOx, GeOx, BOx, AlOx, TiOx, TaOx, nitrides, carbides and borides. The oxides, nitrides, carbides or borides may be stoichiometric or non-stoichiometric oxides, nitrides, carbides or borides. It is possible for the non-etchable dopant to form an oxide, nitride, carbide or boride of an etchable material, i.e. of a material that is removed on contact with the etching medium, as is the case for Si, for example. In this case, the oxide can be SiOx, the nitride can be SiNx, the carbide can be SiCX and the boride can be SiBx. The metal may be a noble metal or a base metal. The oxides, nitrides, carbides or borides may be metal oxides, metal carbides, metal nitrides or metal borides, but may also be oxides, nitrides, carbides or borides of non-metallic materials. It will be understood that it is also possible for a combination of the materials mentioned to be used as the dopant.

In one development of this embodiment, the metal is selected from the group comprising: Ni, Ti, W, Ta, Fe, Mo, Cr, Al, Sc, V, Co, Y, Zr, Nb, Ru, Rh, Hf, Re, Os, Ir, Pt and lanthanides.

The dopant should be as insensitive as possible to the etching medium, so that the dopant can accumulate to a sufficient extent on the surface of the etching front and is not removed when the etchable material is etched away. As described further above, the dopant should also be stable during irradiation with EUV radiation and interfere as little as possible with the further process steps.

In a further embodiment, a doping concentration of the dopant is between 0.01 at% and 30 at%, preferably between 0.1 at% and 20 at%. Doping concentrations in the specified value range have proven to be advantageous.

Depending on the material used as the dopant, higher or lower values of the doping concentration are also possible. Generally, the etchable material can be doped with the dopant at a comparatively high doping concentration, since the etchable material is located below the reflective coating and therefore the effect of the doping on the absorption of the used radiation does not need to be taken into account.

In one embodiment, the etchable material is selected from the group comprising: amorphous silicon (aSi), silicon (Si), SiO2, Si-containing glasses, Ge, GeO, B, BO, materials containing silicon, and further materials that form volatile hydrides with hydrogen can generally be etched by an etching medium in the form of reactive hydrogen or in the form of a hydrogen plasma.

In a further embodiment, the reflective coating has at least one damaged site at which the etchable material is exposed to the surroundings. As described further above, the etching removal of the etchable material begins in the region of the damaged site or below the damaged site in the reflective coating and continues in the lateral direction, wherein the reflective coating is partially underetched. In order to avoid underetching, contact between the etching medium and the etching front is prevented, as has been described further above.

In a further embodiment, the etchable material is contained in an intermediate layer between the reflective coating and the substrate. The intermediate layer is a functional layer that typically does not have an optical function. The intermediate layer can for example be an adhesion promoter layer or a structurable layer, which can be used to form e.g. a grating structure or the like.

In a further embodiment, the etchable material is contained in the substrate. In this embodiment, the substrate itself has the etchable material, which is protected from the etching medium or from the etching removal with the reflective coating. In this case, the reflective coating is typically applied directly to the substrate. However, it is in principle also possible for both the intermediate layer and the substrate to contain an etchable material.

In a further embodiment, the reflective coating forms a multilayer coating for reflecting EUV radiation incident on the reflective optical element with normal incidence, wherein the multilayer coating has alternating layers of a first material and a second material having different refractive indices.

Normal incidence of EUV radiation is typically understood to mean incidence of EUV radiation at an angle of incidence of typically less than approximately 45° to the surface normal of the reflective optical element. The reflective multilayer coating is typically optimized for the reflection of EUV radiation at a predefined wavelength, which generally corresponds to the used wavelength of the EUV lithography system in which the optical element is used. For this purpose, the multilayer coating typically has a multitude of alternating layers of a material having a high real part of the refractive index at the used wavelength and a material having a low real part of the refractive index at the used wavelength. The materials may, for example, be silicon and molybdenum, but other material combinations are also possible depending on the used wavelength.

In a further embodiment, the reflective coating is configured for reflecting EUV radiation incident on the reflective optical element with grazing incidence. Grazing incidence of EUV radiation is typically understood to mean incidence of EUV radiation at an angle of incidence of typically more than approximately 60° to the surface normal of the reflective optical element. A reflective coating configured for grazing incidence typically has a reflectivity maximum at at least one angle of incidence that is greater than 60°. Such a reflective coating is typically formed from at least one material which has a low refractive index and low absorption for the EUV radiation incident with grazing incidence. In this case, the reflective coating can contain a metallic material or can be formed from a metallic material, for example composed of Mo, Ru or Nb.

A further aspect of the invention relates to an EUV lithography system, comprising: at least one optical element as described further above, which is exposed to an etching medium during operation of the EUV lithography system. The EUV lithography system can be an EUV lithography apparatus for exposing a wafer, or can be some other optical arrangement that uses EUV radiation, for example an EUV inspection system, for example for inspecting masks, wafers or the like that are used in EUV lithography. The optical element can be for example an EUV mirror of a projection system or of an illumination system, for example a collector mirror. At least during operation of the EUV lithography system, the optical element and therefore also the reflective coating are exposed to an etching medium, which is typically one or more etching gases that are present in the surroundings of the optical element. The etching medium can be, for example, activated hydrogen or a hydrogen plasma, i.e. excited hydrogen and/or hydrogen radicals.

Further features and advantages of the invention emerge from the following description of exemplary embodiments of the invention on the basis of the figures of the drawing, which show details salient to the invention, and from the claims. The individual features can each be realized individually by themselves or as a plurality in any desired combination in a variant of the invention.

### BRIEF DESCRIPTION OF THE DRAWINGS

Exemplary embodiments are illustrated in the schematic drawing and are explained in the following description. In the figures:

FIG. 1 schematically shows a meridional section through a projection exposure apparatus for EUV projection lithography,

FIGS. 2A and 2B show schematic illustrations, in plan view and in cross-section, respectively, of an EUV mirror of the projection exposure apparatus from FIG. 1 having a substrate and having a reflective coating, which is underetched in the region of a damaged site,

FIGS. 3A and 3B show schematic illustrations of an EUV mirror analogous to FIG. 2B, in which the reflective coating is curved toward the substrate into a cavity in an intermediate layer (FIG. 3A) or in a substrate (FIG. 3B) in surroundings of the damaged site, and

FIGS. 4A-4C show schematic illustrations at three points in time of an EUV mirror, analogous to FIG. 2B, in which an etchable material, located under the reflective coating and doped with a non-etchable dopant, develops a passivation layer.

### DETAILED DESCRIPTION

In the description of the drawings that follows, identical reference signs are used for identical, equivalent, or functionally identical or equivalent components.

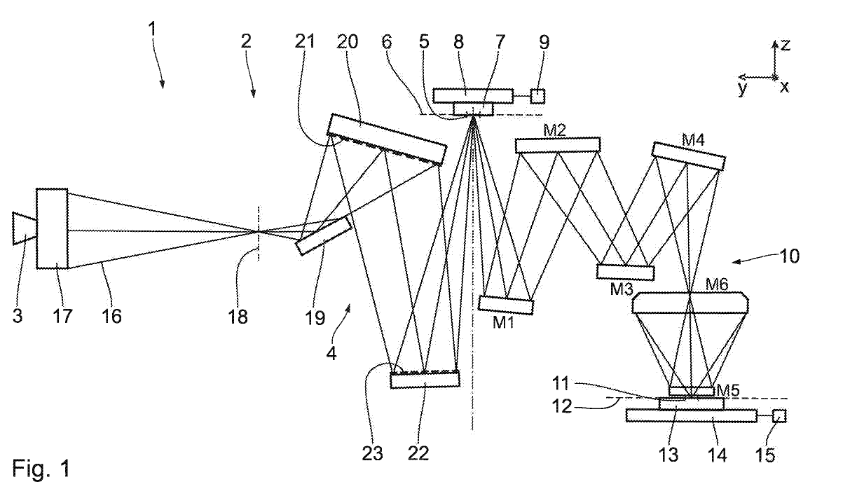

Salient constituent parts of an optical arrangement for EUV lithography in the form of a microlithographic projection exposure apparatus 1 are described by way of example below with reference to FIG. 1. The description of the basic setup of the projection exposure apparatus 1 and the constituent parts thereof should not be understood to have a limiting effect.

One embodiment of an illumination system 2 of the projection exposure apparatus 1 has, in addition to a light or radiation source 3, an illumination optics unit 4 for illuminating an object field 5 in an object plane 6. In an alternative embodiment, the light source 3 may also be provided in the form of a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable, in particular in a scanning direction, by a reticle displacement drive 9.

FIG. 1 shows a Cartesian xyz-coordinate system for explanatory purposes. The x-direction runs perpendicularly to the plane of the drawing into the latter. The y-direction runs horizontally, and the z-direction runs vertically. The scanning direction runs in the y-direction in FIG. 1. The z-direction runs perpendicularly to the object plane 6.

The projection exposure apparatus 1 comprises a projection system 10. The projection system 10 is used to image the object field 5 into an image field 11 in an image plane 12. A structure on the reticle 7 is imaged onto a light-sensitive layer of a wafer 13 that is arranged in the region of the image field 11 in the image plane 12. The wafer 13 is held by a wafer holder 14. The wafer holder 14 is displaceable, in particular in the y-direction, by a wafer displacement drive 15. The displacement, firstly, of the reticle 7 by the reticle displacement drive 9 and, secondly, of the wafer 13 by the wafer displacement drive 15 can be synchronized with one another.

The radiation source 3 is an EUV radiation source. The radiation source 3 emits in particular EUV radiation 16, which is also referred to below as used radiation, illumination radiation or illumination light. The used radiation has in particular a wavelength in the range between 5 nm and 30 nm. The radiation source 3 may be a plasma source, for example a laser-produced plasma (LPP) source or a gas discharge-produced plasma (GDPP) source. It may also be a synchrotron-based radiation source. The radiation source 3 may be a free electron laser (FEL).

The illumination radiation 16 emanating from the radiation source 3 is focused by a collector mirror 17. The collector mirror 17 may be a collector mirror with one or more ellipsoidal and/or hyperboloidal reflection surfaces. The illumination radiation 16 may be incident on the at least one reflection surface of the collector mirror 17 with grazing incidence (GI), i.e. at angles of incidence of greater than 45°, or with normal incidence (NI), i.e. at angles of incidence of less than 45°. The collector mirror 17 may be structured and/or coated, firstly to optimize its reflectivity for the used radiation and secondly to suppress extraneous light.

Downstream of the collector mirror 17, the illumination radiation 16 propagates through an intermediate focus in an intermediate focal plane 18. The intermediate focal plane 18 may constitute a separation between a radiation source module, comprising the radiation source 3 and the collector mirror 17, and the illumination optics unit 4.

The illumination optics unit 4 comprises a deflection mirror 19 and, arranged downstream thereof in the beam path, a first facet mirror 20. The deflection mirror 19 may be a planar deflection mirror or alternatively a mirror with a beam-influencing effect that goes beyond the pure deflection effect. Alternatively or additionally, the deflection mirror 19 may take the form of a spectral filter that separates a used light wavelength of the illumination radiation 16 from extraneous light having a wavelength that deviates therefrom. The first facet mirror 20 comprises a multiplicity of individual first facets 21, which are also referred to below as field facets. FIG. 1 illustrates only some of these facets 21 by way of example. In the beam path of the illumination optics unit 4, a second facet mirror 22 is arranged downstream of the first facet mirror 20. The second facet mirror 22 comprises a plurality of second facets 23.

The illumination optics unit 4 thus forms a doubly faceted system. This fundamental principle is also referred to as a fly's eye integrator. The second facet mirror 22 is used to image the individual first facets 21 into the object field 5. The second facet mirror 22 is the last beam-shaping mirror or actually the last mirror for the illumination radiation 16 in the beam path upstream of the object field 5.

The projection system 10 comprises a plurality of mirrors Mi, which are consecutively numbered in accordance with their arrangement in the beam path of the projection exposure apparatus 1.

In the example illustrated in FIG. 1, the projection system 10 comprises six mirrors M1 to M6. Alternatives with four, eight, ten, twelve or any other number of mirrors Mi are also possible. The penultimate mirror M5 and the last mirror M6 each have a passage opening for the illumination radiation 16. The projection system 10 is a doubly obscured optics unit. The projection optics unit 10 has an image-side numerical aperture which is greater than 0.4 or 0.5 and which may also be greater than 0.6 and which may be for example 0.7 or 0.75.

Just like the mirrors of the illumination optics unit 4, the mirrors Mi may have a highly reflective coating for the illumination radiation 16.

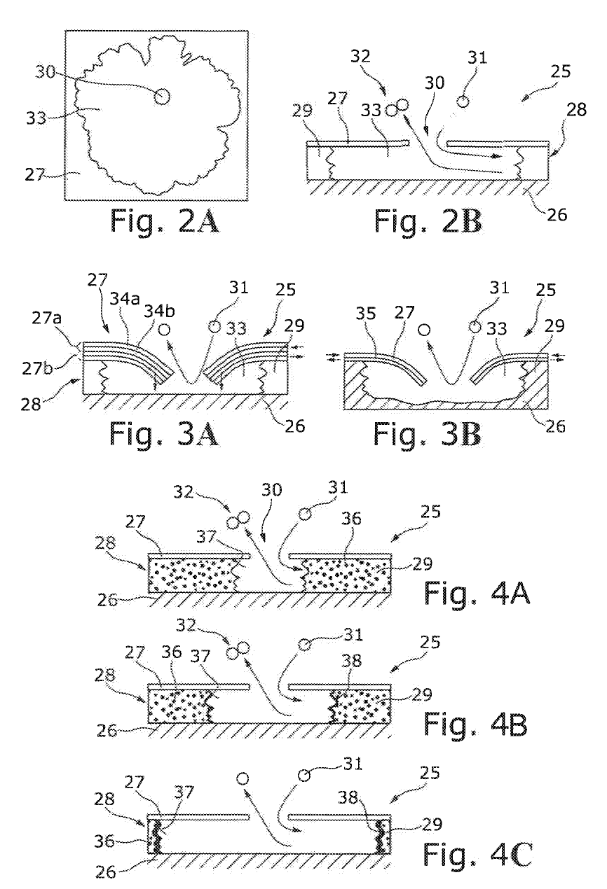

FIGS. 2A and 2B show, in a greatly simplified manner, a detail of a reflective optical element in the form of an EUV mirror 25 of the projection exposure apparatus 1 from FIG. 1, in which the EUV mirror may be, for example, one of the mirrors Mi of the projection optics unit 10, the collector mirror 17 or one of the mirrors 19, 20, 22 of the illumination optics unit 4. The mirror 25 has a substrate 26 and a highly reflective coating 27 for reflecting the EUV radiation 16. An intermediate layer 28, which is covered by the reflective coating 27, is located between the reflective coating 27 and the substrate 25.

The intermediate layer 28 can be used as a structurable layer, e.g. for generating a grating structure (not depicted) or can perform another function. The intermediate layer 28 is formed of a material that can be easily processed by etching. The material of the intermediate layer 28 may be, for example, amorphous silicon, silicon, SiO2, Si-containing glasses, Ge, GeO, B, BO, etc.

As can be seen in the plan view of the reflective coating 27 in FIG. 2A, the reflective coating 27 has a locally delimited damaged site 30 in the form of a hole that extends through the entire thickness of the reflective coating 27. An etching medium 31 in the form of an etching gas, more specifically in the form of activated hydrogen, present in the surroundings of the optical element 25 comes into contact with the material 29 of the intermediate layer 28 via the damaged site 30. The material 29 of the intermediate layer 28 is removed on contact with the etching medium 31, i.e. it is an etchable material that reacts with the etching medium 31 and in so doing forms a volatile material 32. If the etchable material 29 contains silicon, the volatile material 32 may be, for example, a volatile hydride in the form of an SiH compound.

As can be clearly seen in FIG. 2B, the removal of the etchable material 29 is not limited to a volume region of the intermediate layer 28 directly below the damaged site 30, but instead the etchable material 29 is also removed in surroundings of the damaged site 30, the lateral extent of which is significantly greater than the lateral extent of the damaged site 30. This produces an underetched region in the form of a cavity 33 below the damaged site 30 and in the surroundings of the damaged site 30 of the reflective coating 27. In the example shown, the substrate 26 is produced from a material that is not removed on contact with the etching medium 31. The material of the substrate 26 may be, for example, one or more metals, e.g. Ni, Ti, W, Ta, Fe, Mo, Cr, Al, Sc, V, Co, Y, Zr, Nb, Ru, Rh, Hf, Re, Os, Ir, Pt, lanthanides or one or more oxides, e.g. SiOx, GeOx, BOx, AlOx, TiOx, TaOx, or one or more carbides, nitrides or borides.

In order to reduce the lateral extent of the underetched region 33, it is necessary to prevent or reduce the contact between the etching medium 31 and the etchable material 29.

In the example shown in FIGS. 3A and 3B, the lateral extent of the underetched region 33 is reduced by virtue of the reflective coating 27 having a mechanical prestress that causes the reflective coating 27 to curve toward the substrate 26 when the etchable material 29 is removed by the etching medium 31 in the event of damage to the reflective coating 27. As indicated by arrows in FIG. 3A, the mechanical prestress of the reflective coating 27 exerts a bending force or a bending moment on the part of the reflective coating 27 located above the underetched region 33. As a result of the bending force or the bending moment, the reflective coating 27 is curved toward the substrate 26 in the surroundings of the damaged site 30 and projects into the volume of the cavity 33 or of the underetched region. As can be seen in FIGS. 3A, 3B, this restricts or prevents the etching medium 31 from accessing the etchable material 29.

In the example shown in FIG. 3A, the mechanical prestress is generated by virtue of the reflective coating 27 having a first coating portion 27a, which faces away from the substrate 26 and is under a compressive stress, and a second coating portion 27b, which faces toward the substrate 26, is under a tensile stress and directly adjoins the first coating portion 27a in the thickness direction. The tensile stress and the compressive stress are indicated by arrows in FIGS. 3A, 3B.

In the example shown, the reflective coating 27 is a multilayer coating, having alternating layers 34a, 34b of silicon and molybdenum, for reflecting EUV radiation 16 at normal incidence. By way of example, both the first coating portion 27a and the second coating portion 27b each have one pair of alternating layers 34a, 34b of silicon and molybdenum, but in general the number of layer pairs is significantly greater than this. The reflective coating 27 may also have further layers, for example a capping layer, which may be formed e.g. from Ru, or functional layers, e.g. barrier layers, in order to prevent interdiffusion between a respective layer 34a of Si and an adjacent layer 34b of Mo.

In the example shown in FIG. 3A, the first coating portion 27a, more specifically the layers 34a, 34b of the first coating portion 27a, is applied through a coating method that generates a compressive stress, for example by magnetron sputtering. The second coating portion 27b, more specifically the layers 34a, 34b thereof, is applied through a coating method that generates a tensile stress, specifically through electron beam evaporation in the example shown. Alternatively, the second coating portion 27b may be under a compressive stress that is lower than the compressive stress of the first coating portion 27a.

The optical element 25 shown in FIG. 3B differs from the optical element 25 shown in FIG. 3A in that the etchable material 29 is not contained in an intermediate layer, but rather in the substrate 26 itself. In the example shown in FIG. 3B, an underetched region 33 is formed in the manner described in connection with FIGS. 2A, 2B and FIG. 3A. In the case of the optical element 25 shown in FIG. 3B, the reflective coating 27 is configured for reflecting EUV radiation 16 at grazing incidence and has only a single layer composed of a metallic material, more specifically of Ru. The reflective coating 27 in the form of the layer of Ru is, as a whole, under compressive stress. Below the reflective coating 27 there is a layer 35 under tensile stress, which may be formed e.g. from Mo, MoSi, Mo/Si multilayer, MgF2, Ni, Cr or Cr alloys. The compressive stress of the reflective coating 27, together with the tensile stress of the layer 35 under tensile stress, causes the reflective coating 27 to curve toward the substrate 26 or toward the cavity 33 when the etchable material 29 is removed in the surroundings of the damaged site 30. Alternatively, instead of the layer 35 under tensile stress, it is optionally possible to use a layer under compressive stress, the compressive stress of which is lower than the compressive stress of the reflective coating 27.

FIGS. 4A-C show an optical element 25 that differs from the optical element 25 shown in FIGS. 3A, 3B in that the intermediate layer 28 comprising the etchable material 29 is doped with a dopant 36 that is not removed on contact with the etching medium 31. In the example shown, the dopant 36 accumulates at an etching front 37 of the etchable material 29 when the etchable material 29 is removed by the etching medium 31 in the event of damage to the reflective coating 27. As can be seen in FIG. 4B, as the etching removal increases, the thickness of a passivation layer 38 composed of the dopant 36 on or below the etching front 37 increases until the etching removal comes to a complete standstill, as is the case in FIG. 4C .

The dopant 36 may be, for example, one or more metals, in particular Ni, Ti, W, Ta, Fe, Mo, Cr, Al, Sc, V, Co, Y, Zr, Nb, Ru, Rh, Hf, Re, Os, Ir, Pt, lanthanides, one or more oxides, in particular SiOx, GeOx, BOx, AlOx, TiOx, TaOx, or one or more nitrides, carbides or borides. A concentration of the dopant 36 in the etchable material 29 is typically between 0.01 at% and 30 at%, e.g. between 0.1 at% and 20 at%.

It should be understood that the substrate 26 may also be doped with a non-etchable dopant 36 when the substrate 26 has an etchable material 29. In this case too, the etching removal of the etchable material 29 of the substrate 26 may be brought to a standstill in the manner described in connection with FIGS. 4A-C.

The above description of various embodiments has been given by way of example. From the disclosure given, those skilled in the art will not only understand the present invention and its attendant advantages but will also find apparent various changes and modifications to the structures disclosed. The applicant seeks to cover all such changes and modifications as fall within the spirit and scope of the invention, as defined by the appended claims, and equivalents thereof.

What is claimed is:

1. An optical element for reflecting extreme ultraviolet (EUV) radiation, comprising:
a substrate,
a reflective coating configured to reflect the EUV radiation,
an etchable material contained in an intermediate layer between the reflective coating and the substrate and covered by the reflective coating, wherein the etchable material is removed on contact with an etching medium,
wherein the reflective coating is under a mechanical prestress causing the reflective coating to curve toward the substrate when the etchable material is removed by the etching medium and the reflective coating is damaged, and
wherein the reflective coating is under compressive stress at least in a coating portion facing away from the substrate and is under tensile stress at least in a further coating portion facing toward the substrate, and
wherein the etchable material is selected from the group consisting essentially of: amorphous silicon, silicon, SiO₂ Si-containing glasses, Ge, GeO, B and BO.

2. The optical element as claimed in claim 1, wherein at least one layer under tensile stress is arranged between the reflective coating and the etchable material.

3. The optical element as claimed in claim 1, wherein the reflective coating has at least one damaged site at which the etchable material is exposed to surroundings.

4. The optical element as claimed in claim 1, wherein the etchable material is additionally contained in the substrate.

5. The optical element as claimed in claim 1, wherein the reflective coating forms a multilayer coating for reflecting EUV radiation incident on the reflective optical element with normal incidence, and wherein the multilayer coating has alternating layers of a first material and a second material having differing refractive indices.

6. The optical element as claimed in claim 1, wherein the reflective coating is configured to reflect EUV radiation incident on the reflective optical element with grazing incidence.

7. An extreme ultraviolet (EUV) lithography system comprising:
a system environment containing an etching medium, and
a microlithographic projection exposure apparatus comprising plural optical elements including at least one optical element as claimed in claim 1, which is exposed to the etching medium during operation of the microlithographic projection exposure apparatus.

8. An optical element for reflecting extreme ultraviolet (EUV) radiation, comprising:
a substrate,
a reflective coating configured to reflect the EUV radiation,
an etchable material contained in an intermediate layer between the reflective coating and the substrate and covered by the reflective coating, wherein the etchable material is removed on contact with an etching medium,
wherein the etchable material is selected from the group consisting essentially of: amorphous silicon, silicon, SiO₂ Si-containing glasses, Ge, GeO, B and BO, and
wherein the etchable material is doped with a dopant that is not removed on contact with the etching medium, wherein the dopant is selected from the group consisting essentially of: base metals, oxides, SiOₓ, GeOₓ, BOₓ, AlOₓ, TiOₓ, TaOₓ, nitrides, carbides and borides.

9. The optical element as claimed in claim 8,
wherein the dopant accumulates at an etching front of the etchable material when the etchable material is removed by the etching medium and the reflective coating is damaged.

10. The optical element as claimed in claim 8, wherein the base metal is selected from the group consisting essentially of:
Ni, Ti, W, Ta, Fe, Mo, Cr, Al, Sc, V, Co, Y, Zr, Nb, Hf, Re and lanthanides.

11. The optical element as claimed in claim 8, wherein a concentration of the dopant in the etchable material is between 0.01 at% and 30 at%.

12. The optical element as claimed in claim 11, wherein the concentration of the dopant in the etchable material is between 0.1 at% and 20 at%.

13. The optical element as claimed in claim 8, wherein the reflective coating has at least one damaged site at which the etchable material is exposed to surroundings.

14. The optical element as claimed in claim 8, wherein the etchable material is additionally contained in the substrate.

15. The optical element as claimed in claim 8, wherein the reflective coating forms a multilayer coating for reflecting EUV radiation incident on the reflective optical element with normal incidence, and wherein the multilayer coating has alternating layers of a first material and a second material having differing refractive indices.

16. The optical element as claimed in claim 8, wherein the reflective coating is configured to reflect EUV radiation incident on the reflective optical element with grazing incidence.

17. An extreme ultraviolet (EUV) lithography system comprising:
a system environment containing an etching medium, and
a microlithographic projection exposure apparatus comprising plural optical elements including at least one optical element as claimed in claim 8, which is exposed to the etching medium during operation of the microlithographic projection exposure apparatus.
